(19) United States
(12) Patent Application Publication
(10) Pub. No.: US 2025/0293226 A1
(43) Pub. Date: Sep. 18, 2025

(54) LOGIC RECON TO SUPPORT SMALLER LOGIC DIES WITH MEMORY STACKS, AND ASSOCIATED SYSTEMS AND METHODS

(71) Applicant: Micron Technology, Inc., Boise, ID (US)

(72) Inventors: Kunal R. Parekh, Boise, ID (US); Akshay N. Singh, Boise, ID (US)

(21) Appl. No.: 19/069,208

(22) Filed: Mar. 3, 2025

Related U.S. Application Data
(60) Provisional application No. 63/566,586, filed on Mar. 18, 2024.

(51) Int. Cl. H01L 25/18; H01L 23/00; H01L 25/00; H01L 25/16; H10B 80/00; H10D 80/30

(52) U.S. Cl. CPC H01L 25/18; H01L 24/08; H01L 24/24; H01L 24/94; H01L 25/16; H01L 25/50; H10B 80/00; H10D 80/30; H01L 2224/08148; H01L 2224/24146; H01L 2224/94; H01L 2924/1431

(57) ABSTRACT

A method for manufacturing a heterogenous reconstructed wafer is provided. The method includes bonding a plurality of previously-tested main dies to a side of a silicon carrier wafer. The method also includes bonding a plurality of support dies to the side of the silicon carrier wafer such that the plurality of support dies is disposed in gaps between the plurality of main dies. The method also includes filling gaps between the plurality of main dies and the plurality of support dies with a gap-fill material such that the gap-fill material forms a gap-fill layer around and above each of the plurality of main dies and each of the plurality of support dies. The method then includes removing the silicon carrier wafer to form a heterogenous reconstructed wafer.

### CROSS-REFERENCE TO RELATED APPLICATION(S)

The present application claims priority to U.S. Provisional Patent Application No. 63/566,586, filed Mar. 18, 2024, the disclosure of which is incorporated herein by reference in its entirety.

### TECHNICAL FIELD

The present disclosure generally relates to semiconductor device assemblies, and more particularly relates to logic reconstruction to support smaller logic dies with memory stacks.

### BACKGROUND

Microelectronic devices generally have a die (i.e., a chip) that includes integrated circuitry with a high density of very small components. Typically, dies include an array of very small bond pads electrically coupled to the integrated circuitry. The bond pads are external electrical contacts through which the supply voltage, signals, etc., are transmitted to and from the integrated circuitry. After dies are formed, they are “packaged” to couple the bond pads to a larger array of electrical terminals that can be more easily coupled to the various power supply lines, signal lines, and ground lines. Conventional processes for packaging dies include electrically coupling the bond pads on the dies to an array of leads, ball pads, or other types of electrical terminals, and encapsulating the dies to protect them from environmental factors (e.g., moisture, particulates, static electricity, and physical impact).

### BRIEF DESCRIPTION OF THE DRAWINGS

FIG. 1 is a simplified schematic cross-sectional view of an example heterogenous reconstructed wafer in accordance with embodiments of the present technology.

FIG. 2 is a simplified schematic cross-sectional view of another example heterogenous reconstructed wafer in accordance with embodiments of the present technology.

FIG. 3 is a simplified schematic cross-sectional view of yet another example heterogenous reconstructed wafer in accordance with embodiments of the present technology.

FIG. 4 is a schematic view showing a system that includes a semiconductor device assembly configured in accordance with an embodiment of the present technology.

FIG. 5 is a flowchart illustrating a method of manufacturing a heterogenous reconstructed wafer in accordance with embodiments of the present technology.

A person skilled in the relevant art will understand that the features shown in the drawings are for purposes of illustrations, and variations, including different and/or additional features and arrangements thereof, are possible.

### DETAILED DESCRIPTION

The electronics industry relies upon continuous innovation in the field of semiconductor packaging to meet the global need for higher-functioning technology. This demand calls for increasingly complicated assemblies of semiconductor devices, which may diverge in terms of plan area, thickness, connection methodology, etc. When forming and/or stacking dies on a wafer, a single bad die can be enough to ruin an eventual semiconductor device assembly formed by singulating the stack. Therefore, there is a need for separating the bad dies, which can be randomly distributed across the surface of the wafer, from the rest of the dies. One approach to do so is by testing the dies and singulating known good dies (KGDs) from a first wafer and bonding the KGDs to a side of a second wafer.

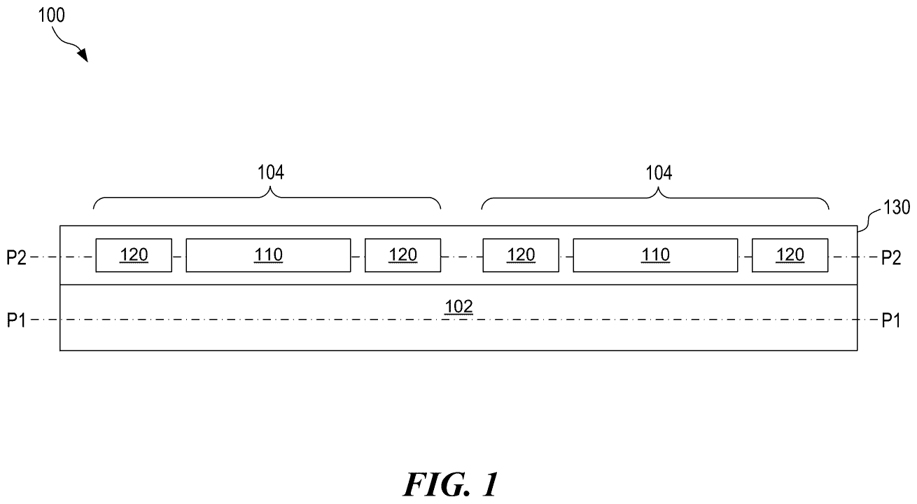

Additional dies that are stacked on top of the KGDs (e.g., memory dies), however, may be of a greater size than each KGD, which can result in unused, and thus wasteful, wafer surface space. One option is to size each KGD to match the larger size of the additional dies that are stacked on top, but this can be impractical, expensive, unnecessary, and similarly wasteful. To address this problem, embodiments of the present technology provide heterogenous reconstructed wafers, as illustrated in FIGS. 1-5.

FIG. 1 is a simplified schematic cross-sectional view of an example heterogenous reconstructed wafer 100 in accordance with embodiments of the present technology. The heterogenous reconstructed wafer 100 can include a plurality of main dies 110, a plurality of support dies 120, and a layer of gap-fill material 130 disposed on a silicon carrier wafer 102. The main dies 110 and the support dies 120 can be bonded to one side of the silicon carrier wafer 102 via, for example, fusion bonding. The gap-fill material layer 130 can be disposed on the same side of the silicon carrier wafer 102. It is appreciated that the dimensions of the components and of the gaps therebetween in the simplified schematic of FIG. 1 are not necessarily to scale.

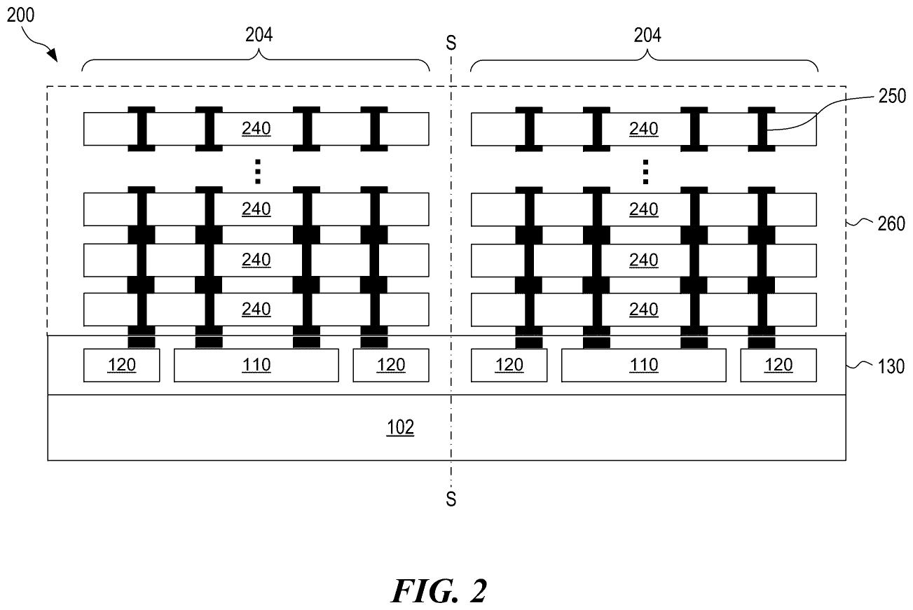

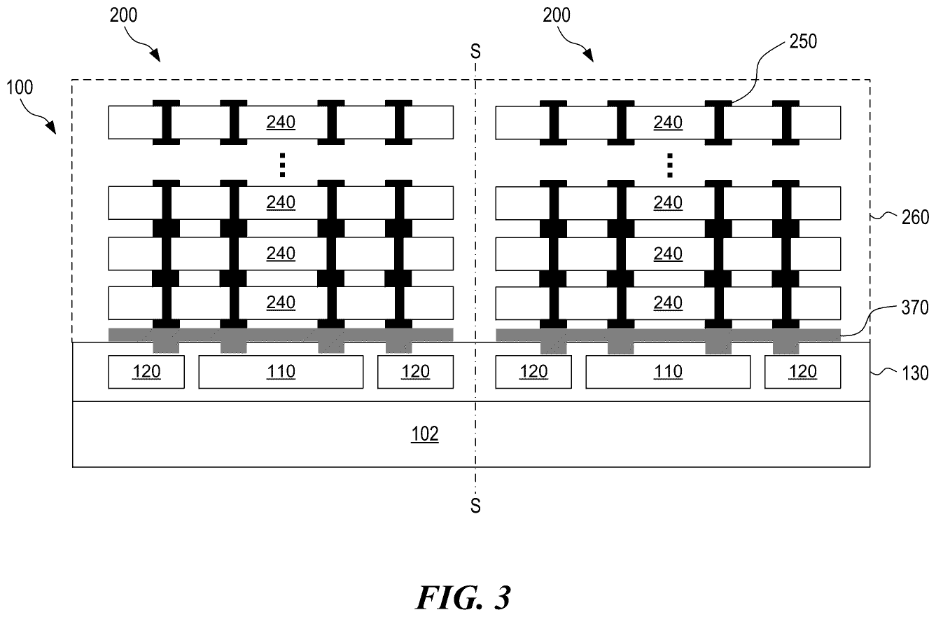

In some embodiments, as discussed above, the main dies 110 are known good dies (KGDs) (e.g., previously-tested main dies) singulated from one or more different wafers (not illustrated). In some embodiments, each main die 110 comprises a logic die configured to perform various logical operations, data processing, etc. In some embodiments, each main die 110 is of sizes between 3-5 nm. Each main die 110 can be bonded to the side of the silicon carrier wafer 102 spaced apart from an adjacent main die 110. For example, the main dies 110 can be arranged in an array across the side of the silicon carrier wafer 102 such that larger dies can be stacked on top (see FIGS. 2 and 3) and/or such that the heterogenous reconstructed wafer 100 can be eventually singulated to form semiconductor device assemblies.

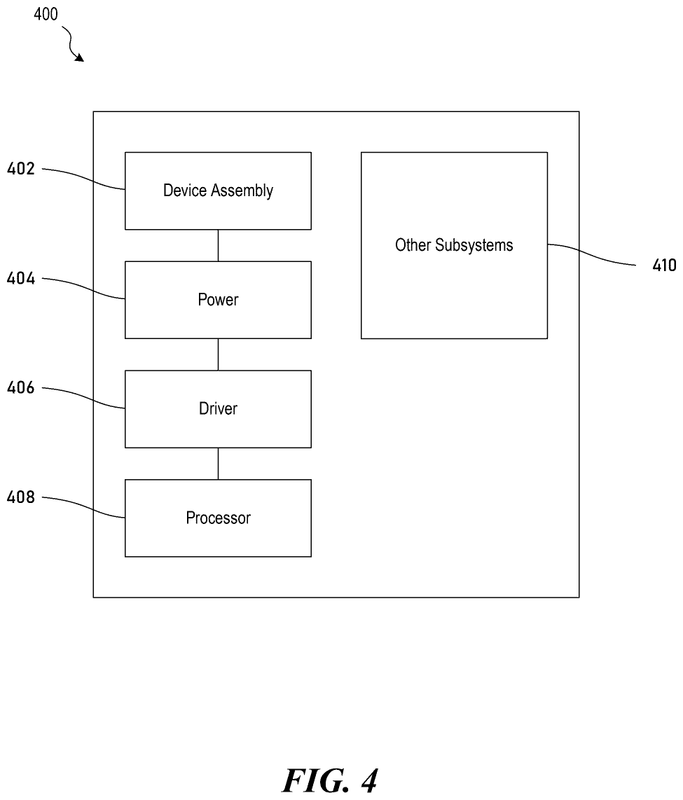

The support dies 120 can be bonded to the same side of the silicon carrier wafer 102. In some embodiments, the silicon carrier wafer 102 lies on a first plane P1, and the main dies 110 and the support dies 120 lie on a second plane P2 parallel to the first plane P1. The support dies 120 can be spaced apart from one another and from the main dies 110. In particular, one or more main dies 110 and one or more support dies 120 can be positioned adjacent to one another to form groups 104. As discussed in further detail below with reference to FIGS. 3 and 4, the groups 104 can eventually be singulated to form semiconductor device assemblies. While two support dies 120 are positioned on either side of a main die 110 in each group 104, each group 104 can include fewer or more support dies 120 positioned adjacent to each main die 110 in other embodiments. Moreover, as FIG. 1 is a cross-sectional view, it is appreciated that each group 104 can include the support dies 120 in various positions around each main die 110 (e.g., into or out of the page). For example, each main die 110 can be positioned adjacent to one, two, three, four, five, six, seven, eight, nine, or more support dies 120. In some embodiments, each group 104 includes more main dies 110 than support dies 120. In some embodiments, different groups 104 have different arrangements of the main dies 110 and the support dies 120.

As discussed further herein, each main die 110 can be of a smaller size than dies to be stacked thereon (e.g., memory dies). Therefore, as the main dies 110 are bonded to the silicon carrier wafer 102 with gaps therebetween to avoid overlap of the larger dies to be stacked thereon, it can be advantageous to include the support dies 120 in those gaps on the second plane P2 and avoid wasting the previous wafer space, as the support dies 120 can provide additional functionality.

In some embodiments, the main dies 110 and the support dies 120 can be different types of dies, hence resulting in the heterogenous reconstructed wafer 100. For example, the main dies 110 can be logic dies and the support dies 120 can be different types of functional dies (e.g., with different circuitry). In some embodiments, each support die 120 comprises one or more passive devices, such as resistors, capacitors, inductors, diodes, transformers, combinations thereof (e.g., an RC network), etc. Passive devices can provide, for example, power management functionality to the eventual semiconductor device assemblies. Such passive devices can require a relatively large amount of space, so including these passive devices in the support dies 120 can both make use of the wafer space in the gaps between the main dies 110 and avoid taking up space elsewhere.

In some embodiments, each support die 120 comprises a pass-through die. The pass-through die can provide additional I/O contact in the eventual semiconductor device assembly, such as for high-bandwidth memory devices, power, ground, command, address, data, etc. In some embodiments, each support die 120 comprises a logic die. The logic die of the support die 120 can be the same as the logic die of the main die 110, or different from the logic die of the main die 110, in which case the heterogenous reconstructed wafer 100 is still heterogenous. For example, types of logic dies include those with basic logic gates, arithmetic logic units (ALUs), memory logic dies, digital signal processor (DSP) dies, graphics processing unit (GPU) dies, artificial intelligence (AI) dies, security logic dies, analog-to-digital (ADC) dies, clock and timing dies, etc.

In some embodiments, each support die 120 comprises a spacer (e.g., without circuitry). For example, the spacer can be made from a thermally conductive material such that the spacer can serve as a heat removal component for the eventual semiconductor device assembly.

The gap-fill material 130 can be applied to fill the gaps between the main dies 110 and the support dies 120 to form the illustrated continuous gap-fill layer. In some embodiments, the gap fill layer can also extend below and/or above the main dies 110 and the support dies 120. The gap-fill material 130 can comprise a dielectric material. For example, the gap-fill material 130 can comprise at least one of silicon oxide, silicon nitride, or silicon carbon nitride. Thus, the gap-fill material 130 can keep the main dies 110 and the support dies 120 insulated from one another. In some embodiments, the top surface of the layer of the gap-fill material 130 can be polished or otherwise planarized (e.g., via chemical mechanical planarization (CMP)) to form a level surface for bonding stacks of other dies thereon, as described in further detail below with respect to FIG. 2.

FIG. 2 is a simplified schematic cross-sectional view of another example heterogenous reconstructed wafer 200 in accordance with embodiments of the present technology. Similar to the heterogenous reconstructed wafer 100 illustrated in FIG. 1, the heterogenous reconstructed wafer 200 includes the main dies 110, the support dies 120, and the layer of the gap-fill material 130 disposed on the silicon carrier wafer 102. The heterogenous reconstructed wafer 200 also includes a plurality of stacked dies 240, Through-Silicon Vias (TSVs) 250, and an encapsulant material 260. The main dies 110, the support dies 120, and the stacked dies 240 can be positioned to form groups 204.

In the illustrated embodiment, the stacked dies 240 are stacked on top of the main dies 110, the support dies 120, and on top of one another. The stacked dies 240 can be bonded to the layer of the gap-fill material 130. Each stacked die 240 can be of a size larger than that of the main die 110. For example, when stacked, the stacked dies 240 can be positioned over the main die(s) 110 and the support dies 120 of the same group 204, as shown. Thus, the support dies 120 can support the stacked dies 240 above. In some embodiments, the sizes of the main dies 110 and the stacked dies 240 are predetermined (e.g., by device requirements), and the sizes and arrangement of the support dies 120 are selected such that the edges of the stacked dies 240 are generally aligned with the edges of the main dies 110 and/or the support dies 120 as defined by the groups 204.

The number of stacked dies 240 in each group 204 can vary. For example, each group 204 can include two, four, eight, sixteen, more, or any number therebetween of stacked dies 240. In some embodiments, the stacked dies 240 comprise memory dies, such as dynamic random access memory (DRAM) dies, NOT-AND (NAND) memory dies, NOT-OR (NOR) memory dies, magnetic random access memory (MRAM) dies, phase change memory (PCM) dies, ferroelectric random access memory (FeRAM) dies, static random access memory (SRAM) dies, or the like. The stacked dies 240 in each group 204 can comprise be memory dies of a same kind (e.g., all NAND, all DRAM, etc.) or memory dies of different kinds (e.g., eight DRAM and eight NAND, etc.).

The stacked dies 240 can be bonded to one another, such as via hybrid bonding. The stacked dies 240 can be electrically connected or coupled to one another, the main dies 110, and/or the support dies 120 by the TSVs 250. In the illustrated embodiment, four TSVs 250 extend vertically through the stacked dies 240 and the layer of the gap-fill material 130, and to the main dies 110 and the support dies 120. In other embodiments, a different number of TSVs 250 can be included in a cross-section of each group 240. In some embodiments, TSVs 250 do not extend to the support dies 120, and instead only extend through and between the stacked dies 240 and the main dies 110. The TSVs 250 can enable data transfer and other forms of communication between the stacked dies 240 and the main dies 110, and/or between the stacked dies 240 and the support dies 120. However, the main dies 110 and the support dies 120 can remain electrically isolated from one another (e.g., due to the dielectric nature of the gap-fill material 130).

The encapsulant material 260 can comprise a resin (e.g., epoxy resin), a polymer composite, or other suitable material. In some embodiments, the encapsulant material 260 can be formed around the stacked dies 240 via a molding process. For example, the heterogenous reconstructed wafer 200 can be positioned in a mold (e.g., in an upright orientation, in an upside-down orientation), and the encapsulant material 260 can be poured or injected into the mold. In another example, the heterogenous reconstructed wafer 200 can be dipped into a mold already containing the encapsulant material 260. The encapsulant material 260 (e.g., once cured) can provide protection for (e.g., by being hard enough), heat dissipation from (e.g., by being relatively thermally conductive), and/or visual inspection of (e.g., by being translucent or transparent) the stacked dies 240 and other components of the eventual semiconductor device assemblies.

The heterogenous reconstructed wafer 200 can then be singulated into a plurality of stacked semiconductor device assemblies. For example, the heterogenous reconstructed wafer 200 can be cut or diced along vertical plane S-S such that each stacked semiconductor device assembly corresponds to a group 204. In some embodiments, the silicon carrier wafer 102 supports additional groups 204 and the heterogenous reconstructed wafer 200 is diced along additional vertical plane S-S not illustrated. In some embodiments, the silicon carrier wafer 102 can be separated or otherwise removed from the main dies 110, the support dies 120, and the gap-fill material 130.

In some embodiments, as discussed above with reference to FIG. 1, the support dies 120 can comprise pass-through dies. For example, the TSVs 250 can extend from the stacked dies 240, through the support dies 120, and to the main dies 110. In another example, the TSVs 250 can extend from the stacked dies 240 to the support dies 120, which can be made from a conductive material and be exposed to serve as additional I/O contact pads once the silicon carrier wafer is separated or otherwise removed from the heterogenous reconstructed wafer 200.

FIG. 3 is a simplified schematic cross-sectional view of yet another example heterogenous reconstructed wafer 300 in accordance with embodiments of the present technology. Similar to the heterogenous reconstructed wafer 200 illustrated in FIG. 2, the heterogenous reconstructed wafer 200 includes the main dies 110, the support dies 120, and the layer of the gap-fill material 130 disposed on the silicon carrier wafer 102, the stacked dies 240 stacked on top of the layer of the gap-fill material 130, and the encapsulant material 260 around the stacked dies 240. The heterogenous reconstructed wafer 300 also includes a remote distribution layer (RDL) 370 bonded to the main dies 110 and the support dies 120.

In the illustrated embodiment, the RDL 370 is disposed as a layer between (i) the main dies 110 and the support dies 120, and (ii) the stacked dies 240 most adjacent to the main dies 110 and the support dies 120. The RDL 370 can be positioned to be surrounded by the gap-fill material 130 and/or the encapsulant material 260. In other embodiments, the RDL 370 can be disposed elsewhere in the heterogenous reconstructed wafer 300. When the heterogenous reconstructed wafer 300 is diced (e.g., along plane S-S) to form semiconductor device assemblies, the RDL 370 can be included in each one of the semiconductor device assemblies.

As discussed above with reference to FIGS. 1 and 2, the main dies 110 and the support dies 120 can be electrically isolated from one another. The RDL 370 can be made from a conductive material to provide electrical coupling between the main dies 110 and the support dies 120. Provide electrical coupling therebetween can be advantageous when, for example, the support dies 120 comprise functional components to be coupled to the main dies 110. In some embodiments, the RDL 370 can be made from a thermally conductive material to provide additional heat dissipation.

FIG. 4 is a schematic view showing a system 400 that includes a semiconductor device assembly 402 configured in accordance with an embodiment of the present technology. Any one of the semiconductor device assemblies that can be manufactured as described above with reference to FIGS. 1-3 can be incorporated into any of a myriad of larger and/or more complex systems, such as the system 400 illustrated. The system 400 can include the semiconductor device assembly (e.g., or a discrete semiconductor device) 402, a power source 404, a driver 406, a processor 408, and/or other subsystems or components 410. The semiconductor device assembly 402 can include features generally similar to those of the semiconductor device assemblies described above with reference to FIGS. 1-3, such as the main dies 110 and the support dies 120 embedded in the continuous layer of the gap-fill material 130. The resulting system 400 can perform any of a wide variety of functions, such as memory storage, data processing, and/or other suitable functions. Accordingly, representative systems 400 can include, without limitation, hand-held devices (e.g., mobile phones, tablets, digital readers, and digital audio players), computers, vehicles, appliances and other products. Components of the system 400 may be housed in a single unit or distributed over multiple, interconnected units (e.g., through a communications network). The components of the system 400 can also include remote devices and any of a wide variety of computer readable media.

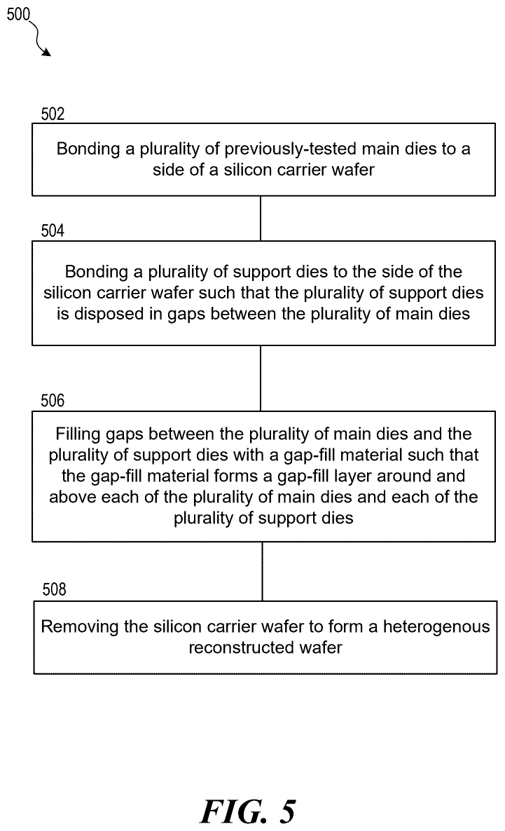

FIG. 5 is a flowchart illustrating a method 500 of manufacturing a heterogenous reconstructed wafer in accordance with embodiments of the present technology. The method 500 can include, at block 502, bonding a plurality of previously tested main dies (e.g., the main dies 110) to a side of a silicon carrier wafer (e.g., the silicon carrier wafer 102). The method 500 can include, at block 504, bonding a plurality of support dies (e.g., the support dies 120) to the side of the silicon carrier wafer such that the plurality of support dies is disposed in gaps between the plurality of main dies. The method 500 can include, at block 506, filling gaps between the plurality of main dies and the plurality of support dies with a gap-fill material (e.g., the gap fill material 130) such that the gap-fill material forms a gap-fill layer around and above each of the plurality of main dies and each of the plurality of support dies. The method 500 can include, at block 508, removing the silicon carrier wafer to form the heterogenous reconstructed wafer (e.g., the heterogenous reconstructed wafer 100).

In some embodiments, the method 500 can additionally include bonding a plurality of memory dies (e.g., the stacked dies 240) to the gap-fill layer such that the plurality of memory dies is positioned over at least one of the plurality of main dies and at least one of the support dies. The method 500 can also include encapsulating the plurality of memory dies with an encapsulant (e.g., the encapsulant material 260) and singulating the heterogenous reconstructed wafer (e.g., along plane S-S) into a plurality of stacked semiconductor device assemblies. The method 500 can also include bonding the plurality of memory dies to at least one of the plurality of main dies or the plurality of support dies using one or more Through-Silicon Vias (e.g., the TSVs 250).

In some embodiments, the method 500 can additionally include bonding a remote distribution layer (e.g., the RDL 370) to the plurality of main dies and the plurality of support dies. The remote distribution layer can be configured to provide electrical coupling between the plurality of main dies and the plurality of support dies. The method 500 can also include planarizing (e.g., polishing) the gap-fill layer to prepare the gap-fill layer for bonding (e.g., to the stacked dies 240).

In some embodiments, each of the plurality of main dies comprises a logic die. In some embodiments, each of the plurality of support dies comprises a logic die, a passive device (e.g., a resistor, an inductor, a capacitor), a pass-through die, or a spacer. In some embodiments, the silicon carrier wafer is positioned on a first plane (e.g., the first plane P1), and the plurality of main dies and the plurality of support dies are positioned on a second plane (e.g., the second plane P2) parallel to the first plane.

Specific details of several embodiments of semiconductor devices, and associated systems and methods, are described above. A person skilled in the relevant art will recognize that suitable stages of the methods described herein can be performed at the wafer level or at the die level. Therefore, depending upon the context in which it is used, the term “substrate” can refer to a wafer-level substrate or to a singulated, die-level substrate. Furthermore, unless the context indicates otherwise, structures disclosed herein can be formed using conventional semiconductor-manufacturing techniques. Materials can be deposited, for example, using chemical vapor deposition, physical vapor deposition, atomic layer deposition, plating, electroless plating, spin coating, and/or other suitable techniques. Similarly, materials can be removed, for example, using plasma etching, wet etching, chemical-mechanical planarization, or other suitable techniques.

The devices discussed herein, including a memory device, may be formed on a semiconductor substrate or die, such as silicon, germanium, silicon-germanium alloy, gallium arsenide, gallium nitride, etc. In some cases, the substrate is a semiconductor wafer. In other cases, the substrate may be a silicon-on-insulator (SOI) substrate, such as silicon-on-glass (SOG) or silicon-on-sapphire (SOP), or epitaxial layers of semiconductor materials on another substrate. The conductivity of the substrate, or sub-regions of the substrate, may be controlled through doping using various chemical species including, but not limited to, phosphorous, boron, or arsenic. Doping may be performed during the initial formation or growth of the substrate, by ion-implantation, or by any other doping means.

The functions described herein may be implemented in hardware, software executed by a processor, firmware, or any combination thereof. Other examples and implementations are within the scope of the disclosure and appended claims. Features implementing functions may also be physically located at various positions, including being distributed such that portions of functions are implemented at different physical locations.

As used herein, including in the claims, “or” as used in a list of items (for example, a list of items prefaced by a phrase such as “at least one of” or “one or more of”) indicates an inclusive list such that, for example, a list of at least one of A, B, or C means A or B or C or AB or AC or BC or ABC (i.e., A and B and C). Also, as used herein, the phrase “based on” shall not be construed as a reference to a closed set of conditions. For example, an exemplary step that is described as “based on condition A” may be based on both a condition A and a condition B without departing from the scope of the present disclosure. In other words, as used herein, the phrase “based on” shall be construed in the same manner as the phrase “based at least in part on.”

As used herein, the terms “vertical,” “lateral,” “upper,” “lower,” “above,” and “below” can refer to relative directions or positions of features in the semiconductor devices in view of the orientation shown in the Figures. For example, “upper” or “uppermost” can refer to a feature positioned closer to the top of a page than another feature. These terms, however, should be construed broadly to include semiconductor devices having other orientations, such as inverted or inclined orientations where top/bottom, over/under, above/below, up/down, and left/right can be interchanged depending on the orientation.

It should be noted that the methods described above describe possible implementations, and that the operations and the steps may be rearranged or otherwise modified and that other implementations are possible. Furthermore, embodiments from two or more of the methods may be combined.

From the foregoing, it will be appreciated that specific embodiments of the invention have been described herein for purposes of illustration, but that various modifications may be made without deviating from the scope of the invention. Rather, in the foregoing description, numerous specific details are discussed to provide a thorough and enabling description for embodiments of the present technology. One skilled in the relevant art, however, will recognize that the disclosure can be practiced without one or more of the specific details. In other instances, well-known structures or operations often associated with memory systems and devices are not shown, or are not described in detail, to avoid obscuring other aspects of the technology. In general, it should be understood that various other devices, systems, and methods in addition to those specific embodiments disclosed herein may be within the scope of the present technology.

What is claimed is:

1. A method for manufacturing a heterogenous reconstructed wafer, the method comprising:
bonding a plurality of previously-tested main dies to a side of a silicon carrier wafer;
bonding a plurality of support dies to the side of the silicon carrier wafer such that the plurality of support dies is disposed in gaps between the plurality of main dies;
filling gaps between the plurality of main dies and the plurality of support dies with a gap-fill material such that the gap-fill material forms a gap-fill layer around and above each of the plurality of main dies and each of the plurality of support dies; and
removing the silicon carrier wafer to form a heterogenous reconstructed wafer.

2. The method of claim 1, further comprising:
bonding a plurality of memory dies to the gap-fill layer such that the plurality of memory dies is positioned over at least one of the plurality of main dies and at least one of the support dies.

3. The method of claim 2, further comprising:
encapsulating the plurality of memory dies with an encapsulant; and
singulating the heterogenous reconstructed wafer into a plurality of stacked semiconductor device assemblies.

4. The method of claim 2, further comprising:
bonding the plurality of memory dies to at least one of the plurality of main dies or the plurality of support dies using one or more through-silicon vias.

5. The method of claim 1, wherein each of the plurality of support dies comprises a logic die.

6. The method of claim 1, wherein each of the plurality of support dies comprises a passive device.

7. The method of claim 1, further comprising:
bonding a remote distribution layer to the plurality of main dies and the plurality of support dies, wherein the remote distribution layer is configured to provide electrical coupling between the plurality of main dies and the plurality of support dies.

8. The method of claim 1, further comprising:
planarizing the gap-fill layer to prepare the gap-fill layer for bonding.

9. The method of claim 1, wherein the silicon carrier wafer is positioned on a first plane, and wherein the plurality of main dies and the plurality of support dies are positioned on a second plane parallel to the first plane.

10. A heterogenous reconstructed wafer, the wafer comprising:
a plurality of previously-tested main dies;
a plurality of support dies disposed in gaps between the plurality of main dies; and
a continuous gap-fill material disposed between and above each of the plurality of main dies and each of the plurality of support dies, wherein the gap-fill material comprises a dielectric material.

11. The heterogenous reconstructed wafer of claim 10, wherein the gap-fill material comprises at least one of silicon oxide, silicon nitride, or silicon carbon nitride.

12. The heterogenous reconstructed wafer of claim 10, further comprising:
a plurality of memory dies bonded to the gap-fill material, wherein the plurality of memory dies is positioned over at least one of the plurality of main dies and at least one of the support dies.

13. The heterogenous reconstructed wafer of claim 12, wherein each of the plurality of main dies has a first size, wherein each of the plurality of support dies has a second size, and wherein each of the plurality of memory dies has a third size greater than the first size and the second size.

14. The heterogenous reconstructed wafer of claim 10, further comprising:
a remote distribution layer bonded to the plurality of main dies and the plurality of support dies, wherein the remote distribution layer is configured to provide electrical coupling between the plurality of main dies and the plurality of support dies.

15. The heterogenous reconstructed wafer of claim 10, wherein each of the plurality of support dies comprises a logic die.

16. The heterogenous reconstructed wafer of claim 10, wherein each of the plurality of support dies comprises a passive device.

17. The heterogenous reconstructed wafer of claim 10, wherein each of the plurality of support dies comprises a pass-through die configured to provide IO contacts.

18. A heterogenous reconstructed wafer, the wafer comprising:
a previously-tested main die positioned on a first plane;
a support die disposed adjacent to the main die and on the first plane; and
a continuous gap-fill material disposed between and above the main die and the support die, wherein the gap-fill material comprises a dielectric material.

19. The heterogenous reconstructed wafer of claim 18, further comprising a plurality of memory dies stacked on top of the main die, the support die, and one another, wherein the plurality of memory dies comprises at least 16 memory dies.

20. The heterogenous reconstructed wafer of claim 18, wherein the gap-fill material comprises at least one of silicon oxide, silicon nitride, or silicon carbon nitride.
